(19) United States
(12) Patent Application Publication
(10) Pub. No.: US 2026/0056473 A1
(43) Pub. Date: Feb. 26, 2026

(54) Catoptric System Using Scheimpflug Optics

(71) Applicant: KLA Corporation, Milpitas, CA (US)

(72) Inventors: Yasuhiro Hidaka, San Jose, CA (US); Junwon Lee, San Jose, CA (US)

(73) Assignee: KLA Corporation, Milpitas, CA (US)

(21) Appl. No.: 19/282,489

(22) Filed: Jul. 28, 2025

Related U.S. Application Data
(60) Provisional application No. 63/686,179, filed on Aug. 23, 2024.

(51) Int. Cl. G03F 7/00; G02B 17/06

(52) U.S. Cl. CPC G03F 7/70233; G02B 17/0694

(57) ABSTRACT

A catoptric (mirror-based) optical system uses Scheimpflug optics and non-concentric optics to generate unobscured highly magnified images (e.g., >100×) in EUV reticle inspection tools. The Scheimpflug optics collect light beams from an object plane and directs the light beams along a first optical axis to generate an intermediate image at an intermediate image plane that is oblique to the object plane. The non-concentric optics redirect the light beams from the first optical axis to a second optical axis that is perpendicular to the intermediate image plane and generates a magnified image on a final image plane that is parallel to the intermediate image plane. The Scheimpflug optics may include a first mirror positioned to collect light beams reflected normal to the object plane and a second mirror positioned adjacent to the normal direction and configured to redirect the light beams onto the first optical axis.

### RELATED APPLICATIONS/PATENTS

This application claims priority from U.S. Provisional Patent Application No. 63/686,179, entitled “SCHEIMPFLUG OPTICS WITH HIGH MAGNIFICATION”, which was filed on Aug. 23, 2024.

### FIELD OF DISCLOSURE

The present application relates to catoptric systems and methods, and more particularly to high-magnification catoptric systems and to high-energy IC manufacturing systems (e.g., EUV reticle inspection tools) that utilize high-magnification catoptric systems.

### RELATED ART

Semiconductor fabrication typically involves a series of fabrication steps during which integrated circuits (ICs) are gradually created on a silicon wafer or other suitable substrate. Each fabrication step typically includes both photolithographic and physio-chemical processes. The photolithographic process of each fabrication step typically involves applying a layer of photoresist (photosensitive material) over the substrate (i.e., on the substrate's surface or on a material layer on the substrate's surface), utilizing a mask/reticle to expose a patterned portion of the photoresist layer to light, and then developing the exposed photoresist layer portions to create a pattern of developed resist structures and intervening openings. A corresponding physio-chemical process (e.g., etching, chemical vapor deposition, or ion implantation) is then performed through the openings between the developed photoresist structures. Each fabrication step can be thought of as producing a corresponding patterned layer of conductive, semiconductor, and insulating structures that are vertically aligned with corresponding underlying structures, whereby the stacked layers collectively form the electronic circuitry and connective wiring of a desired IC (e.g., a microprocessor, a microcontroller and/or memory structure).

Process nodes (aka technology nodes or process technologies) are currently used to identify generational advances in semiconductor fabrication technologies. That is, various market factors compel the continued development of semiconductor fabrication technologies capable of producing ever smaller, faster and more efficient ICs. Early semiconductor fabrication technologies were identified using arbitrary names and associated ordinal numbers, and advances in each technology were indicated by incremental changes in the associated ordinal number. Later, each new semiconductor fabrication technology generation was identified by a process node that designated the technology generation's minimum feature size (e.g., the “90 nm process”). More recently, the number of nanometers used to name process nodes has become more of a marketing term that has no standardized relation with functional feature sizes or with transistor density (number of transistors per unit area). However, each progressively smaller process node numerical designation typically indicates decreased fabrication cost (e.g., by increasing the number of IC devices that can be fabricated on each silicon wafer), increased performance (e.g., processing speed) and/or increased energy efficiency (e.g., battery life) in comparison to ICs produced using process nodes having larger numerical designations.

A key component in the continued development of ever-smaller process nodes is the wavelength of light utilized during the photolithographic process to fabricate ICs. In the 1960s, photolithographic processes used mercury-vapor lamps to generate visible light having a wavelength of 435 nm that was directed through relatively large reticle openings to facilitate the fabrication of IC feature sizes of about 20 μm. Subsequent advances to the photolithographic process allowed for some reduction in feature size, but the relatively long wavelength of visible light proved to limit the smallest IC feature sizes that could be imaged through reticle openings. To overcome this problem, photolithographic processes transitioned from visible light to ultraviolet (UV) light (e.g., having wavelengths of 365 nm or 248 nm) generated by excimer lasers. The switch to UV light and associated UV-developed photoresists facilitated the fabrication of ICs having minimum features sizes below 1 μm. Deep UV (DUV) lithography is relatively recently developed semiconductor fabrication technology that utilizes 193 nm light from argon-fluoride (ArF) lasers to achieve a resolution of as low as 38 nm. Extreme ultraviolet lithography (EUVL) represents a cutting-edge semiconductor fabrication technology that utilizes extreme ultraviolet (EUV) light at 13.5 nm emitted from a laser-pulsed tin (Sn) plasma to fabricate ICs at 10 nm process nodes and smaller (as of 2023, EUVL systems targeting 5 nm and 3 nm process nodes were under development).

One of the technical problems associated with the transition from UV and DUV lithography systems to EUVL systems was the development of reflective optical systems capable of imaging patterned EUV light onto photoresist with a sufficiently high resolution. That is, UV and DUV lithography systems utilize transmissive (lens-based) optical systems that achieve relatively high resolution by configuring extremely accurate lenses to direct light along the system's optical axis through patterned reticle openings and to focus the patterned light onto a photoresist layer (wafer), which is maintained normal (perpendicular) to the optical axis. Unfortunately, transmissive optical systems cannot be used in EUVL systems because, unlike UV and DUV light, EUV light is absorbed by glass, thereby precluding the use of both lenses and light transmissive reticles. Accordingly, reflective optical systems have been developed for EUVL systems that utilize a mirror-based optical system to both direct EUV light from a source onto a reflective (mirror-based) reticle and to image the light pattern from the reflective reticle onto a photoresist layer (wafer).

FIG. 7 depicts a greatly simplified EUVL system 70 including an EUV light source 71 and a reflective optical system 73 that is configured to transfer an EUV light pattern (structured information) from a reflective reticle (photomask) 80 onto a substate (e.g., a silicon wafer) 85. An upper surface of reticle 80 defines an object plane OP including an exemplary pattern of reflective multilayer micro-mirrors 81 that are surrounded by absorber (EUV absorbing material) 82. An upper surface of substate 85 defines an image plane IP includes a layer of photoresist onto which the pattern of micro-mirrors 86 is transferred. Note that reticle 80 and substrate 85 are depicted in FIG. 7 in rotated orientations for descriptive purposes (i.e., as indicated by the X-Y-Z coordinate axes, the upper surface of reticle 80 and the upper surface of substrate 85 are disposed in parallel X-Y planes). EUV light source 71 directs pulses from an IR laser 71-1 onto tin microdroplets to create a highly ionized tin plasma 71-2 that emits EUV light 72. Optical system 73 includes illuminating optics 74 that collects and directs a portion of EUV light 72 onto reticle 80, and imaging (projection) optics 75 that collect EUV light reflected from micro-mirrors 81 and transfer the resulting EUV light pattern onto photoresist 86. Specifically, illuminating optics 74 includes a multilayer collector mirror 74-1 that collects and focuses in-band EUV light 72-1 emitted from tin plasma 71-2, and one or more illuminator mirrors 74-2 that homogenize and direct EUV light 72-1 onto reticle 80 by way of a pupil (not shown). Reticle 80 convert incident homogenous EUV light 72-1 into reflected light pattern (specularly reflected light) 72-2 by reflecting portions by the incident EUV light that are directed onto reflective regions 81 and absorbing (not reflecting) portions of the incident EUV light directed onto absorber 82. Imaging optics 75 includes a first imaging mirror 75-1 that is configured to collect reflected light pattern 72-2 and a second imaging mirror 75-2 to magnify and focus reflected light pattern 72-2 onto photoresist 86. Although not shown in FIG. 7, one or both of reticle 80 and substrate 85 is/are moved in their respective X-Y planes and EUV light source 71 is controlled to facilitate transferring reflected light pattern 72-2 onto multiple exposure regions 87-1 to 87-4 on photoresist layer 86, whereby each of these regions is caused to contain a corresponding pattern of exposed photoresist portions 86-1 surrounded by non-exposed photoresist 86-2 that corresponds to the pattern of reflective regions 81 disposed on reticle 80. Note again that the example depicted in FIG. 7 is greatly simplified for descriptive purposes (e.g., due to Optical Proximity Correction, the shape of reflective regions 81 is typically quite different from the shape of imaged/exposed photoresist portions 86-1), and that the EUVL systems description herein omit certain specific details for brevity.

Although the shorter wavelength of EUV light provides EUVL systems with a significant advantage over UV and DUV lithography systems, the required switch from transmissive optics to reflective optics presents several technical problems that must be overcome in order to achieve ever-smaller IC feature sizes. That is, the smallest IC feature size (single patterning resolution limit) achievable by EUVL system 70 depends on the optical resolution of optical system 73, which is determined by the combined performance of illumination optics 74 and imaging/projection optics 75. One way to achieve higher optical resolution is to increase the numerical aperture (NA) of imaging/projection optics 75. However, as explained below with reference to FIGS. 8A to 10B, increasing the NA of imaging/projection optics 75 is limited by the use of reflective reticle 80.

FIGS. 8A and 8B respectively depict reticle 80 and substrate 85 during the exposure of a portion 86-11 of photoresist layer 86 by EUV light reflected from a micro-mirror 81-1 on reticle 80. Referring to FIG. 8A, dashed line P indicates a direction perpendicular to the upper surface of reticle 80 (i.e., parallel to the Z-axis). Incident light portion 72-11 depicts homogenous EUV light that is focused and directed by illuminating mirror 74-2 onto micro-mirror 81-1, and reflected light portion 72-211 depicts a portion of reflected light pattern 72-2 that is redirected by micro-mirror 81-1 toward first imaging mirror 75-1. Note that, in order to accurately transfer light patterns from reflective reticle 80, incident light 72-11 cannot overlap with reflected light 72-211, and therefore must be directed at a sufficient angle relative to perpendicular P to prevent overlap (i.e., unlike UV and DUV lithography systems in which light is directed perpendicularly through a transmissive reticles and onto a wafer). For example, as depicted in FIG. 8A, incident light portion 72-11 is directed toward micro-mirror 81-1 such that a chief ray angle at object (CRAO-1), which is measured between perpendicular P and a chief ray CR₇₂₋₁₂ of incident light 72-11, and reflected light portion 72-11 is directed away from micro-mirror 81-1 such that its chief ray CR₇₋₂₁₁ is also equal to CRAO-1 (e.g., 6°). Referring to FIG. 8B, light portion 72-212 depicts reflected light portion 72-211 (FIG. 8A) after being redirected and focused by second imaging mirror 75-2 onto exposed photoresist portion 86-11. By selecting a sufficiently large CRAO-1 (e.g., 6°) and by configuring the optics such that numerical aperture NA₇₂₋₂₁₁ of reflected light portion 72-11 is sufficiently small (e.g., 0.08), reflected light portion 72-212 is directed by imaging optics 75 onto substrate 85 with a numerical aperture NA₇₃₋₂₁₂ of 0.33 and a magnification factor of four.

FIGS. 9A to 10B depict the consequences of increasing the numerical aperture on the magnification factor of imaging/projection optics 75 used by EUVL system 70 (shown in FIG. 7). FIGS. 9A and 9B show that modifying the imaging optics to increase the numerical aperture NA₇₃₋₂₂₂ of reflected light portion 72-222 at wafer 85 (FIG. 9B) from 0.33 to 0.5 while maintaining CRAO-1 at 6° necessitates an associated increase in the numerical aperture NA₇₋₂₁ of reflected light portion 72-221, thereby causing an intersection (overlap) of incident light 72-12 and reflected light 72-221 (as indicated by darkened overlap region OL). This intersection (overlap) of incident light 72-12 and reflected light 72-221 results in significant contrast loss, which can significantly reduce production yields. FIGS. 10A and 10B depict another example in which the numerical aperture NA₇₃₋₂₃₂ of reflected light portion 72-232 at wafer 85 (FIG. 10B) is 0.5, and the overlap issue shown in FIG. 10A is prevented by modifying both the illumination and imaging optics to increase CRAO-2 from 6° to 9°. However, this approach results in increased absorber shadowing that produced low production yields.

In addition to the development of photolithographic systems capable of generating integrated circuits, the integrated circuit industry requires inspection systems (inspection tools) that are capable of detecting and correcting defects (flaws) occurring in photomasks and reticles before they are utilized by a given photolithographic system to produce integrated circuits. Such inspection tools are required by IC makers to facilitate the detection of defects whose sizes are of the order of, or smaller than, the feature sizes generated by a selected process node, and are therefore required to achieve a magnification of 100× or more. Moreover, such inspection tools are required by IC makers to facilitate inspection using light having a wavelength identical, or close, to the wavelength that will be used for photolithography, as the phase-shifts of the inspection light caused by the reticle patterns will be identical or very similar to those caused during photolithography. In addition, a pellicle (not shown), which is used to prevent the particles from landing on the reticle patterns is typically only transmissive to the wavelength used for lithography.

The development of EUVL inspection tools (e.g., inspection tools for inspecting the reflective reticles utilized in EUVL systems) has been hampered by optical system challenges similar to those described above with reference to EUVL systems. That is, in order to meet the industry requirement for inspection using EUV light, EUVL inspection tools must utilize mirror-based optical systems that direct EUV light to and reflect EUV light from an EUV (reflective) reticle onto a suitable detector (e.g., a Time Delay Integration (TDI) sensor). Moreover, detecting reticle defects that are significantly smaller than the smallest IC feature size is currently one of the most critical issues to be addressed for commercialization of EUV lithography. That is, due to the complex multi-layer mirror structures utilized by EUV reticles, atomic scale height (0.3-0.5 nm) defects are capable of causing significant yield losses and can take many forms. For example, defects can be buried underneath, within or on top of the multilayer mirror stack, and/or mesas or protrusions may form the sputtering targets used for multilayer deposition, which may fall off as particles during the multilayer deposition. Furthermore, the edge of a phase defect will further reduce reflectivity by more than 10% if its deviation from flatness exceeds 3 degrees. These and other possible EUV reticle defects call for EUVL inspection tools capable of high magnification (e.g., 100× or more) and with high resolution. Moreover, providing an EUVL inspection tool with optics configured to direct/collect EUV light at angles that are as close possible to the optical axis has proven effective in increasing reflectivity, which improves the EUVL inspection tool's sensitivity to the defect detection (e.g., the ability to detect the various defect forms mentioned above). Accordingly, the optical systems currently utilized by EUVL systems are inadequate for use in EUVL inspection systems because they are incapable of meeting either the high magnification or the close-to-normal incidence angle requirements (e.g., EUVL optical system 70 achieves relatively low magnification (4× or 8×) and illumination optics has a chief ray angle to object CRAO-1 of at least) 6°.

FIG. 11 shows a partial prior art EUV reticle inspection tool 90 including imaging optics 95 that meet the close-to-normal incidence angle requirement and also generates images at a suitably high (e.g., 100×) magnification. Although omitted from FIG. 11 for clarity, EUV inspection tool 90 also includes a EUV light source and illumination optics that function in a manner similar to that described above with reference to EUVL system 70 (FIG. 7) to direct EUV light onto reticle 80 at an incidence angle. Imaging optics 95 includes four mirrors 95-1 to 95-4 that magnify EUV light reflected from reticle 80 and generate a corresponding image on a suitable image collection device (e.g., a TDI sensor) 87. As depicted in FIG. 11, EUV light 92-1 is reflected from reticle 80 (e.g., from micro-mirror 86-2) and is collected by mirror 95-1, which redirects and focuses the collected light onto mirror 95-2 (as indicated by second light portion 92-2). Mirror 95-2 is positioned and configured to reflect second light portion 92-2 along optical axis OA, which is perpendicular (normal) to the upper surface of reticle 80, to mirror 95-3 (as indicated by third light portion 92-3). Mirror 95-3 is positioned and configured to reflect third light portion 92-3 toward imaging mirror 95-4 (as indicated by fourth light portion 92-4), which in turn redirects and focuses (images) the reflected light onto image sensor 87 (as indicated by fifth light portion 92-5). When mirrors 95-1 to 95-4 are suitably configured, imaging optics 95 is capable of imaging reticle 80 onto image sensor 87 with high magnification (e.g., 100× to 600×).

Although conventional EUV inspection tool 90 achieves desirably high magnification and meets the close-to-normal incidence angle requirements, imaging optics 95 introduces an obscuration that reduces the intensity and resolution of the magnified image projected onto image sensor 87, thereby making it difficult for conventional EUV inspection tool 90 to detect reticle flaws. This obscuration is caused for two main reasons. The first reason is that imaging optics 95 utilizes concentric optics in order to simplify both the design and the optical alignment of mirrors 95-1 to 95-4 (i.e., all four mirrors 95-1 to 95-4 are aligned along optical axis OA and that the field of view is located close to optical axis OA). The second reason is that, as indicated in FIG. 12, in order to facilitate high magnification (e.g., 100× or more), the concentric mirrors must be configured such that a fraction of reflected light portion 92-1 is blocked by mirror 92-2. FIG. 12 depicts a profile (e.g., as imaged through a pupil) of light portion 92-1 as it passes from reticle 80 to mirror 95-1 (as shown in FIG. 11), where shaded region 92-1O depicts an exemplary fraction of light portion 92-1 that is blocked (obscured) by mirror 92-2. Note that the location of obscuration (region 92-1O) coincides with optical axis OA (i.e., reflected EUV beams that are transmitted on or close to perpendicular from reticle 80 are blocked/obscured by mirror 95-2). Although the size of obscuration 92-1O comprises a relatively small percentage (<10%) of the reflected EUV light passed through the pupil, the location of obscuration 92-1O on optical axis OA causes a significant degradation in both the resolution and intensity of the magnified image. That is, as mentioned above, EUV light beams that are reflected in the normal/perpendicular direction from reticle 80 (i.e., along optical axis OA) have a higher intensity than light beams directed at an angle to the normal/perpendicular direction (e.g., indicated by region 92-11 in FIG. 12). Therefore, obscuration 92-1O significantly reduces the overall intensity of light portion 92-1, which reduces both the intensity (photons per unit area) and resolution of the acquired reticle image data (e.g., referring to FIG. 11, the intensity and resolution of focused light portion 92-5 received by image sensor 87). Because inspection tools typically detect flaws by comparing and detecting differences between acquired reticle image data and stored known-good reticle image data, it is very important for the acquired reticle image data to have the highest possible intensity and resolution. Although the intensity and resolution of acquired reticle image data generated by imaging optics 95 may be sufficient to detect EUV reticle flaws, the degradation caused by obscuration 92-1O makes flaw detection difficult and time-consuming (e.g., EUV inspection tool 90 often must perform multiple reticle scans and process significantly more image data to detect some reticle flaws). Therefore, the loss of image data conveyed by the EUV light beams that are blocked by mirror 95-2 degrades the magnified image more than the ratio of the obscuration and thus limits the ability of current EUVL reticle inspection tools to efficiently detect all of the various defects that can occur in EUV reticles.

Note that the obscuration issue mentioned above cannot be avoided in reticle inspection systems by adapting an off-axis optics approach similar to that currently utilized by some EUVL systems because the off-axis optics approach generates an image having an image size that is equal to the size of the field of view multiplied by the magnification of the imaging/projecting optics. Although the resulting image height would be relatively easily accommodated when used to generate images at relatively low (4×) magnifications (i.e., a 10-millimeter-wide (10 mm) field of view and a 4× magnification would produce an image having a width of 40 mm, which is well within the size range that can be captured using existing imaging sensors), the off-axis optics approach is problematic if used to generate image at high magnifications (i.e., assuming a 10 mm field of view and 100× magnification, the resulting image would have an image height/width of approximately one meter, which would require an impractically large image sensor). For this reason, all currently commercially available EUV reticle inspection tools utilize an optical system that exhibits the obscuration issue described above.

What is generally needed is a catoptric (mirror-based optical) system and associated method that are capable of producing high magnification (e.g., 100× or higher) images using electromagnetic radiation having wavelengths shorter than 121 nm (e.g., EUV light and X-ray radiation) while avoiding the obscuration issue described above with reference to existing EUV reticle inspection tools. What is also needed is an inspection tool that utilizes the catoptric system to generate high magnification, high resolution images suitable for detecting the various flaws associated with EUV reticles.

### SUMMARY

In an embodiment, the present invention is directed to a catoptric (mirror-based/reflective optical) system that utilizes a combination of Scheimpflug optics and non-concentric optics to generate highly magnified images (e.g., 100× or more) in a way that avoids the obscuration issue associated with conventional EUV reticle inspection tools. The magnified image is generated on a final image plane using patterned light beams that are sourced (i.e., reflected or emitted) from an imaged area (e.g., specular light reflected from the micro-mirrors of an EUV reticle or from another object) located on an object plane. The Scheimpflug optics include two or more mirrors collectively configured and arranged in accordance with the Scheimpflug condition to collect the patterned light beams sourced from the imaged area and to redirect the light beams along a first optical axis such that the redirected light beams form an intermediate image at an intermediate image plane that is oblique to the object plane (i.e., such that the first optical axis forms a first oblique angle relative to a direction that is normal to the object plane, and such that the intermediate image plane forms a second oblique angle relative to the object plane). By redirecting the light beams at an oblique angle relative to the normal direction, the Scheimpflug optics facilitate avoiding the obscuration issue caused by the optical systems currently utilized by EUV inspection tools (i.e., by facilitating capturing light beams reflected in the normal direction from the object plane). By avoiding the obscuration issue, the Scheimpflug optics serve to significantly increase the intensity and resolution of the acquired reticle image data, which in turn increases a reticle inspection tool's ability to detect and correct defects/flaws, and facilitates the use of simple pupil shapes, such as ellipse or circular shape. Note, however, that the intermediate image generated by the Scheimpflug optics is formed/focused on an image plane that is oriented at a (third) oblique angle relative to the first optical axis. That is, the light receiving/detecting surface of an image sensor would have to be tilted at the (third) oblique angle relative to the light beams exiting the Scheimpflug optics to properly capture the focused intermediate image. This tilted sensor orientation is problematic because existing image sensors are configured to efficiently capture incident light that is directed substantially perpendicular (normal) to the image sensor's light receiving/detecting surface, but light received at oblique angles is often reflected (not captured), whereby image data generated in response to obliquely received light would be incomplete (degraded). The non-concentric optics includes two or more additional mirrors that are configured and arranged to correct the oblique light beam problem by normalizing the image plane (i.e., redirecting the light beams from the first optical axis to a second optical axis that is normal/perpendicular to the intermediate image plane). By combining the obscuration avoidance benefits provided by the Scheimpflug optics with the image plane normalization benefits provided by the non-concentric optics, the catoptric system facilitates the generation of unobscured, highly magnified images having substantially higher resolution than comparable images generated by conventional EUV reticle inspection tools.

In an embodiment, the Scheimpflug optics includes two (first and second) concave mirrors that are configured in accordance with known techniques to reflect high energy light. For example, in one specific embodiment, each of the first and second mirrors comprises a multilayer mirror stack of the type utilized in EUVL systems and EUV reticle inspection tools. The first mirror is positioned/oriented to collect light beams reflected from the imaged area of the object plane (e.g., a portion of the planar upper surface of an EUV reticle) and to reflect (redirect) the captured light beams along a first optical path toward the second mirror. The first mirror is configured (shaped) such that the light beams converge as they pass along the first optical path, such that the focal plane of the first mirror is located between the first mirror and the second mirror, whereby the light beams passing along the first optical path invert before arriving at the second mirror. The second mirror is positioned to reflect the light beams passed along the first optical path from the first mirror such that the reflected light beams are redirected along the first optical axis. The second mirror is configured (shaped) such that the light beams converge as they pass along the first optical axis and form the intermediate image at the intermediate image plane. The second mirror is offset from the region directly above the imaged area to avoid obscuration. In presently preferred embodiments, the first and second mirrors are configured such that the first oblique angle is in the range of 1° and 10°, and more preferably in the range of 1.5° and 2.5°. Configuring the first and second mirrors in the above manner provides the Scheimpflug optics with the desired obscuration avoidance and magnification in the range of 5× to 30×. In other embodiments, the Scheimpflug optics may be implemented using three or more mirrors, for example, to achieve higher magnification.

In alternative specific embodiments, the Scheimpflug optics may be implemented using either concave spherical mirrors or concave aspherical (e.g., even asphere or Zernike asphere) mirrors. In a first exemplary embodiment, the reflective surface shape of both mirrors is spherical, and both mirrors are positioned such that their respective centers of curvature are on located on the first optical axis. In a second exemplary embodiment, the reflective surface shape of both mirrors is aspherical, and both mirrors are positioned such that their respective symmetric axes are located on the first optical axis. Spherical mirrors are easier to fabricate and therefore less expensive than aspherical mirrors, but in some cases (e.g., EUV inspection tools) the diffraction limit of spherical mirrors may require the use of aspherical mirrors.

In some embodiments, the non-concentric optics include a third mirror that is positioned and configured to redirect light beams from the first optical axis onto a second optical path, and one or more additional (fourth) mirrors positioned and configured to reflect the light beams from the second optical path onto the second optical axis and to focus the reflected light beams on a final image plane magnify and direct the redirected light beams along the second optical axis. In one embodiment, the non-concentric optics normalize the image plane by configuring the third mirror such that the light beams directed by the third mirror along the second optical path remain substantially parallel between the third mirror and the one or more additional (fourth) mirrors, and such that the second optical path forms a (fourth) oblique angle relative to the first optical axis. In alternative specific embodiments, the third mirror either comprises a convex mirror located between the intermediate image plane and the second convex mirror, or a concave mirror located between the intermediate image plane and the final image plane. In some embodiments a fourth mirror comprises a concave mirror configured to magnify the redirected light beams directed along the second optical axis such that the magnified image is formed on the final image plane. In presently preferred embodiments the intermediate image plane is located between the fourth mirror and the final image plane. Configuring the third and fourth mirrors in the above manner provides the non-concentric optics with the desired image plane normalization and magnification in the range of 10× to 50×.

In another embodiment, the present invention is directed to an inspection system including a first stage (e.g., X-Y table) configured to support and move (scan) an object (e.g., an EUV reticle), an illumination unit configured to generate and direct homogenous light onto the object (reticle), a second stage configured to support and move (scan) an image sensor in synchronization with scanning of the reticle, wherein the inspection system utilizes the catoptic optical system (described above) to project and magnify patterned light reflected from the object (reticle) onto the image sensor, and whereby the inspection system generates high resolution, high magnification image data that avoids the obscuration issue associated with conventional EUV inspection tools.

In another embodiment the present invention is directed to a method for inspecting an object (e.g., reticle) disposed in an object plane including: directing homogenous incident light onto the object; utilizing Scheimpflug optics to collect light beams reflected from the object and to redirect the light beams along a first optical axis such that the redirected light beams form an intermediate image at an intermediate image plane, both the first optical axis and the intermediate image plane being oblique to the object plane; utilizing non-concentric optics to redirect the light beams from the first optical axis to a second optical axis that is perpendicular to the intermediate image plane such that the redirected light beams form the magnified image at a final image plane that is parallel to the intermediate image plane; and utilizing an image sensor disposed in the final image plane to capture the magnified image.

### BRIEF DESCRIPTION OF FIGURES

FIG. 1 is a side view depicting a catotropic optical system according to an embodiment.

FIGS. 2A and 2B are side views depicting a portion of the reflective optical system including Scheimpflug optics configured in accordance with alternative exemplary embodiments.

FIGS. 3A and 3B are side views illustrating problems associated with the use of Scheimpflug optics (alone) to generate high magnification images.

FIG. 4 is a side view depicting a reflective optical system according to another embodiment.

FIG. 5 is a ray tracing diagram depicting high magnification characteristics achieved by the catotropic optical system of FIG. 1 according to an exemplary embodiment.

FIG. 6 is a side view depicting a simplified inspection tool including the catotropic optical system of FIG. 1 according to another embodiment.

FIG. 7 is a partial perspective view showing a conventional EUVL system.

FIGS. 8A and 8B are side views depicting a reticle and a substrate, respectively, during operation of the EUVL system of FIG. 7.

FIGS. 9A and 9B are side views depicting a reticle and a substrate, respectively, and depict consequences of increasing the numerical aperture of imaging/projection optics used by the EUVL system of FIG. 7 according to a first example.

FIGS. 10A and 10B are side views depicting a reticle and a substrate, respectively, and depict consequences of increasing the numerical aperture of imaging/projection optics used by the EUVL system of FIG. 7 according to a second example.

FIG. 11 is a side view showing a partial conventional EUV inspection tool.

FIG. 12 is a top view depicting a profile of light captured by the conventional EUV inspection tool of FIG. 11.

### DETAILED DESCRIPTION OF THE DRAWINGS

The following description is presented to enable one of ordinary skill in the art to make and use the methods and systems described herein as provided in the context of exemplary embodiments. Various additional simplifications and modifications, which will be apparent to those with skill in the art, are utilized for brevity and clarity. Therefore, the methods and systems described herein are not intended to be limited to the particular embodiments shown and described but are to be accorded the widest scope consistent with the principles and novel features herein disclosed.

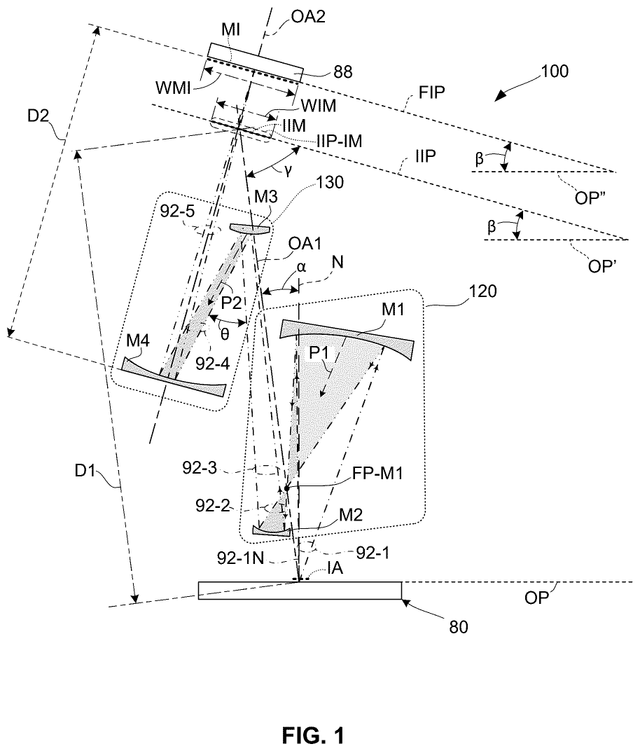

FIG. 1 shows a catoptric (mirror-based/reflective optical) system 100 according to an exemplary embodiment. Catoptric system 100 includes Scheimpflug optics 120 and non-concentric optics 130 that collectively project and magnify patterned light sourced from an imaged area IA residing in an object plane OB to generate a focused, highly magnified image MI of imaged area IA at a final image plane FIP. In some embodiments, both Scheimpflug optics 120 and non-concentric optics 130 comprise multilayered mirrors of the type utilized in EUVL systems and EUV reticle inspection tools (i.e., configured to reflect extreme ultraviolet light having a nominal wavelength of 13.5 nm). In alternative embodiments, Scheimpflug optics 120 and non-concentric optics 130 are configured as described below such that a size (e.g., width WMI) of highly magnified image MI is in the range of 50× (fifty times) to 1000× the size (width) of imaged area IM.

Scheimpflug optics 120 include a first concave mirror M1 and a second concave mirror M2 that are collectively configured and arranged in accordance with the Scheimpflug condition to collect the patterned light beams 92-1 from an imaged area IA residing in an object plane OB, and to redirect patterned light beams 92-3 along a first optical axis OA1 in a way that forms an intermediate image IIM in an intermediate image plane IIP. Arranging mirrors M1 and M2 such that they satisfy the Scheimpflug condition facilitates orienting first optical axis OA1 at an oblique angle relative to the object plane OP (such that first optical axis OA1 extends at a first oblique angle α relative to the normal direction N of object plane OP. Satisfying the Scheimpflug condition also causes intermediate image plane IIP to form a second oblique angle β with object plane OP (e.g., as indicated at the upper right portion of FIG. 1, where object plane OP′ is parallel to object plane OP).

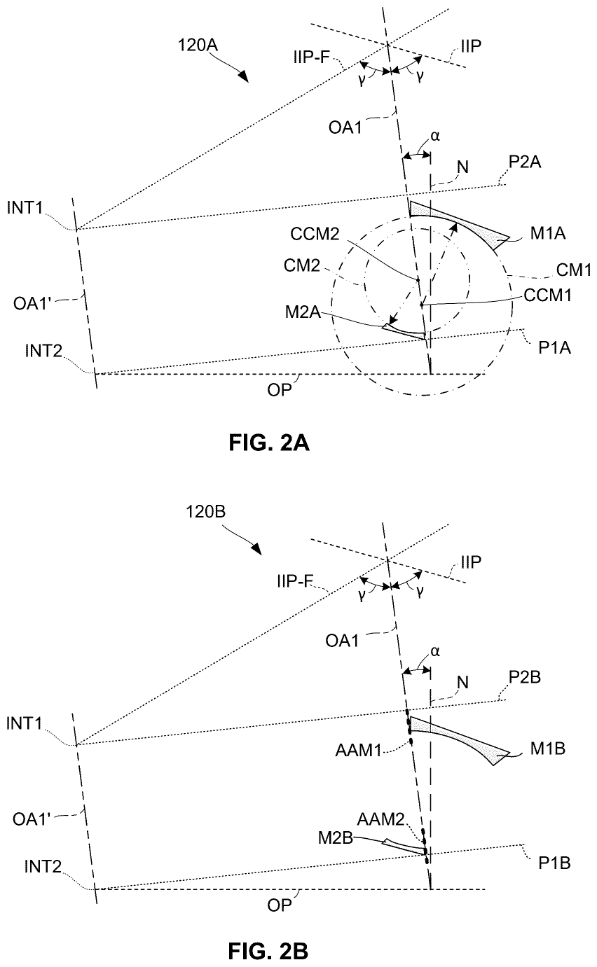

First mirror M1 is positioned over object plane OP and configured/oriented to collect and reflect (redirect) light beams 92-1 sourced from imaged area IA such that the reflected (redirected) light beams 92-2 converge along a first optical path P1. At least a portion of mirror M1 is located directly over imaged area IA such that normal light beams 92-1N (i.e., a portion of light beams 92-1 directed in normal direction N from imaged area IA) are collected and redirected along first optical path P1. First mirror M1 is further configured and positioned such that its focal plane point FP-M1 is located between first mirror M1 and second mirror M2, whereby the light beams 92-2 passing along first optical path P1 is inverted before arriving at second mirror M2 (as set forth below with reference to FIGS. 2A and 2B, the inversion of light beams 92-2 is important to the arrangement of mirrors M1 and M2 such that they satisfy the Scheimpflug condition).

Second mirror M2 is positioned and oriented over object plane OP and adjacent to imaged area M2 to receive and redirect inverted light beams 92-2 directed by first mirror M1 along first optical path P1 such that redirected light beams 92-3 are redirected along first optical axis OA1. Second mirror M2 is configured (shaped) such that light beams 92-3 converge as they pass along first optical axis OA1 from second mirror M2 and focus to form intermediate image AI when they arrive at intermediate image plane IP1. To avoid the obscuration issue, the position of second mirror M2 is adjacent to but offset from the region immediately above imaged area IA (i.e., such that normal light beams 92-1N passing from imaged area IA to first mirror M1 are not impeded by any portion of mirror M2). To facilitate the placement (location) of second mirror M2 with a suitable offset, first oblique angle α must be greater than a non-zero amount (e.g., greater than) 0.5° but should be less than or equal to 10° to avoid significant aberrations. It is possible to avoid obscuration using a first oblique angle α of at least 0.5°, but undesirable aberrations (e.g., COMA and astigmatism) are caused at larger tilt angles (e.g., when Scheimpflug optics 120 are configured and arranged such that first oblique angle α is greater than) 10°. In practical embodiments, obscuration may be avoided using Scheimpflug optics 120 configured/arranged such that first oblique angle α is in the range of 0.5° to 2.5°, and more preferably approximately 2°.

FIGS. 2A and 2B respectively depict Scheimpflug optics 120A and 120B according to alternative specific embodiments. Both Scheimpflug optics 120A (FIG. 2A) and Scheimpflug optics 120B (FIG. 2B) include two concave mirrors that are arranged and configured as described above to direct patterned light from object plane OP along first optical axis OA1. For clarity and brevity, it is assumed that Scheimpflug optics 120A and Scheimpflug optics 120B share the same first optical axis OA1 and both form an intermediate image the same intermediate image plane IIP (i.e., in both examples first optical axis OA1 forms first oblique angle α with normal direction N and forms a third oblique angle γ with intermediate image plane IIP), although in practical applications these planes/axes may differ from each other.

Referring to FIG. 2A, Scheimpflug optics 120A are characterized in that both a first mirror MIA and a second mirror M1B are concave spherical mirrors. That is, the concave reflective surface of first mirror MIA conforms with a first spherical curvature CM1 (indicated by dash-dot line) having a corresponding center of curvature CCM1, and the concave reflective surface of second mirror M2A conforms with a second spherical curvature CM2 (indicated by dash-dot-dot line) having a corresponding center of curvature CCM2. According to the first embodiment, both first concave spherical mirror MIA and second concave spherical mirror M2A are positioned and arranged such that both center of curvature CCM1 and center of curvature CCM2 coincide with corresponding locations along first optical axis OA1 (i.e., both centers of curvature CCM1 and CCM2 define optical axis OA1, and optical axis OA1 is positioned.

Referring to FIG. 2B, Scheimpflug optics 120B are characterized in that both first mirror M1B and second mirror M2B are concave aspherical mirrors (e.g., even asphere of Zernike asphere) having corresponding symmetric axes. That is, the concave reflective surface of first mirror M1B conforms with a selected aspherical shape having a first symmetric axis AAM1, and the concave reflective surface of second mirror M2B conforms with a second aspherical shape having a corresponding second symmetric axis AAM2, where both axes AAM1 and AAM2 are indicated in FIG. 2B by corresponding thick dashed line segments. According to the second embodiment, both first concave aspheric mirror MIA and second concave aspheric mirror M2A are positioned and arranged such that both first symmetric axis AAM1 and second symmetric axis AAM2 coincide with corresponding locations along first optical axis OA1.

FIGS. 2A and 2B also illustrate how the mirrors of Scheimpflug optics 120A and 120B may be further configured to satisfy the Scheimpflug condition. Satisfying the Scheimpflug condition is relatively straight forward when the optics comprise a single thin lens having a single principal plane (referred to as a lens plane). In this simple case, the lens is oriented such that the lens plane, the object plane and the image plane all intersect at a single line (sometimes referred to as a Scheimpflug intersection). However, in the case of more complex optical arrangements (e.g., a thick lens, multiple lenses or, as in the case of Scheimpflug optics 120A and 120B, multiple mirrors), the Scheimpflug condition is satisfied when the two principle planes (principal surfaces) defined by the optical arrangement respectively intersect the object plane and the image plane along lines that can be joined by a plane (or line) that is parallel to the optical axis of the optical arrangement. Note that, as in the case of Scheimpflug optics 120A and 120B, the image plane must be flipped relative to the optical axis when the image is inverted (i.e., as discussed above with reference to FIG. 1, light beams 92-2 are inverted because focal point FP-M1 is located between mirrors M1 and M2, so the image passed along optical axis OA1 is inverted). Referring to FIG. 2A, exemplary principal planes P1A and P1B defined by mirrors MIA and M2A are indicated, along with a flipped intermediate image plane IIP-F, which is generated by flipping intermediate image plane IIP around first optical axis OA1 (i.e., such that both planes IIP and IIP-F diverge from first optical axis OA1 by third oblique angle γ). In this example, Scheimpflug optics 120A satisfy the Scheimpflug condition because principal plane PIA intersects flipped intermediate image plane IIP-F at intersection line INT1, principal plane P2A intersects object plane OP at intersection line INT2, and intersection lines INT1 and INT2 can be connected by a line/plane OA1′ that is parallel to first optical axis OA1. Similarly, as indicated in FIG. 2B, Scheimpflug optics 120B satisfy the Scheimpflug condition because principal planes P1B and P2B, which are defined by mirrors M1B and M2B, intersect with flipped intermediate image plane IIP-F and object plane OP at intersection lines INT1 and INT2 that can be connected by a line/plane OA1′. The planes OP, IIP, IIP-F, PIA and P2A and the lines INT1 and INT2 are all orthogonal to the plane that the optical axis OA1 and the line N determine.

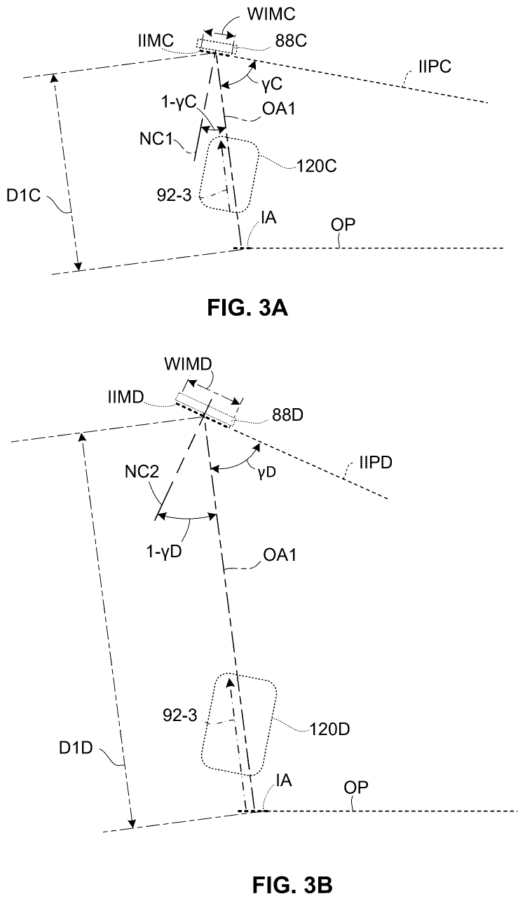

Scheimpflug optics 120 generates intermediate image IIM and intermediate image plane IIP with characteristics (i.e., location, size, orientation) that are determined in part by the magnification of Scheimpflug optics 120. As is understood in the art, the magnification of Scheimpflug optics 120 may be changed (increased or decreased) by way of changing the curvature of mirrors M1 and/or M2. In the example depicted in FIG. 1, the location of intermediate image IIM relative to the object plane (i.e., a distance D1 along first optical axis OA1), the size (e.g., the width WIM) of intermediate image IIM and the slope/orientation of intermediate image plane IIP relative to object plane OP (i.e., second oblique angle β) are determined by the combined magnification mirrors M1 and M2. As discussed below with reference to FIGS. 3A and 3B, the location and size of intermediate image IIM and the orientation intermediate image plane IIP change in direct proportion to the combined magnification mirrors M1 and M2, and it not practical to capture/record intermediate image IIM using currently available image sensor technology, particularly when mirrors M1 and M2 are modified to generate intermediate image IIM at high magnification. That is, currently available image sensor technologies are configured to efficiently capture incident light that is directed substantially perpendicular (normal) to the image sensor's light receiving/detecting surface, but light received at sufficiently large oblique angles is often reflected (not captured), which greatly reduces the image sensor's efficiency.

FIGS. 3A and 3B respectively depict Scheimpflug optics 120C and 120D in which the combined magnification of the two mirrors (not shown for clarity) varies significantly. Referring to FIG. 3A, when the combined magnification of Scheimpflug optics 120C is relatively low, intermediate image IIMC is generated at a relatively short distance DIC along first optical axis OA1 and has a relatively small size/width WIMC relative to imaged area IA. In addition, third obtuse angle γC between intermediate image plane IIPC and first optical axis OA1 is relatively large, meaning that pattern light beams 92-3 are directed at an incidence angle 1-γC relative to normal direction NC1 (i.e., the direction perpendicular to intermediate image plane IIPC). FIG. 3A also depicts a hypothetical image sensor 88C arranged such that its light receiving surface is positioned and oriented (i.e., parallel to intermediate image plane IIPC) to capture intermediate image IIMC. Note that incidence angle 1-γC relative to normal direction NC1 is relatively small, whereby it may be possible for image sensor 88C to capture at least some of patterned light beams that form intermediate image IIMC. Referring to FIG. 3B, when the combined magnification of Scheimpflug optics 120D is relatively high, intermediate image IIMD is generated at a relatively long distance DID from object plane OP and has a relatively large size/width WIMD. However, the increased magnification decreases third obtuse angle YD, whereby incidence angle 1-γD is relatively large in relation to normal direction NC1 (i.e., the direction perpendicular to intermediate image plane IIPD), which makes it more difficult (or impossible) for a hypothetical image sensor 88D to capture intermediate image IIMD. Moreover, Scheimpflug optics is based on the theory of magnification in transverse and longitudinal directions; that is, achieving high magnification (100×) in the transverse direction produces a longitudinal magnification of 10000×, which requires an incidence angle 1-γD (image plane tilt) of almost 90°, making it impossible for image sensor 88D to capture any of patterned light beam 92-3.

Referring again to FIG. 1, catoptric system 100 utilizes non-concentric optics 130 to facilitate both high magnification and image capture of patterned light beams 92-3 exiting Scheimpflug optics 120. That is, non-concentric optics 130 includes a third mirror M3 and one or more fourth mirrors M4 that are collectively configured to redirect patterned light beams 92-3 from first optical axis OA1 to a “non-concentric” (different) second optical axis OA2 such that the redirected light beams become focused at a distance D2 along second optical axis OA2 to generate final magnified image MI on a final (second) image plane FIP. By configuring mirrors M3 and M4 such that “non-concentric” second optical axis OA2 is perpendicular to intermediate image plane IIP and such that final image plane FIP is parallel to intermediate image plane IP1, non-concentric optics 130 facilitates efficient image capture by positioning image sensor 88 on second optical axis OA2 and orienting the light receiving surface of image sensor 88 in final image plane FIP. In addition, non-concentric optics 130 facilitate generating the final magnified image MI at desired magnification (e.g., 100×, 200×, etc.) by way of modifying the curvature of mirror M4.

In the embodiment depicted in FIG. 1, non-concentric optics 130 includes a (third) mirror M3 and at least one (fourth) mirror M4. Non-concentric optics 130 function to normalize the image plane by configuring mirror M3 such that patterned light beams 92-4, which are by redirected mirror M3 from first optical axis OA1 to a second optical path P2, remain substantially parallel between mirror M3 and mirror M4, and such that second optical path P2 forms a (fourth) oblique angle θ relative to first optical axis OA1. That is, mirrors M3 and M4 collectively form an optical subsystem having an optical axis (i.e., second optical axis OA2) that differs from first optical axis of Scheimpflug optics 120. Note also that non-concentric optics 130 is configured such that intermediate image plane IIP forms an object plane for the optical subsystem formed by mirrors M3 and M4. Configuring mirrors M3 and M4 in manner set forth below facilitates producing non-concentric optics 130 with the desired image plane normalization and magnification in the range of 10× to 50×.

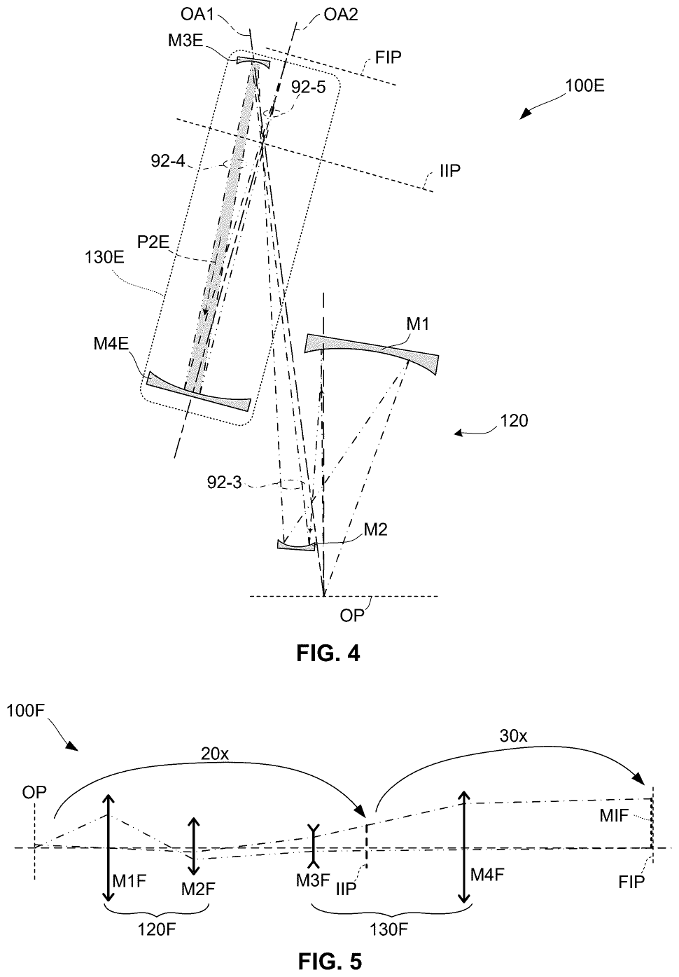

In alternative embodiments, (third) mirror M3 may be implemented using a convex spherical mirror or a concave spherical mirror. In the embodiment shown in FIG. 1, mirror M3 comprises a convex spherical mirror that is located between intermediate image plane IIP and second mirror M2. In an alternative embodiment shown in FIG. 4, optical system 100E includes Scheimpflug optics 120 configured as described above and non-concentric optics 130E including a (third) mirror M3E that is positioned between second mirror M2 and intermediate image plane IIP and is configured and oriented to reflect light beams 92-3 such that reflected light beams 92-4 are redirected in parallel along a second optical path P2E toward (fourth) mirror M4E. However, since second mirror M2 is a concave mirror, it may be advantageous to use convex mirror M3 (FIG. 1) to reduce the petzval field curvature.

Mirror M4 is configured and oriented to reflect patterned light beams 92-4 such that reflected light beams 92-5 are redirected along second optical axis OA2 to final image plane FIP. In some embodiments mirror M4 comprises a concave mirror configured to magnify parallel light beams 92-4 received from mirror M3 such that diverging light beams 92-5 directed along second optical axis OA2 focuses to generate magnified final image MI at final image plane FIP. In presently preferred embodiments mirror M4 is configured such that intermediate image plane IIP is located between mirror M4 and final image plane FIP (e.g., as depicted in FIG. 2). In other embodiments (not shown), mirror M4 may be configured such that final image plane FIP is located in front of or coplanar with intermediate image plane IIP.

FIG. 5 shows a ray tracing diagram for a catotropic optical system 100F configured to generate a magnified image MIF at final image plane FIP with a six-hundred-times (600×) magnification. In this embodiment Scheimpflug optics 120F include mirror M1F and M2F configured to generate an intermediate image (i.e., at intermediate image plane IIP) with a magnification of 20×, and non-concentric optics 130F including mirrors M3F and M4F configured magnified image MIF with the desired 600× magnification by magnifying the intermediate image by an additional 30×. In other embodiments, Scheimpflug optics 120F may be configured to generate an intermediate image with a magnification in the range of 5× to 30×, and non-concentric optics 130F may be configured to magnify the intermediate image by an additional amount in the range of 10× to 50×. In some embodiments, the combined magnification of Scheimpflug optics 120F and non-concentric optics 130F is in the range of 50× to 1000×.

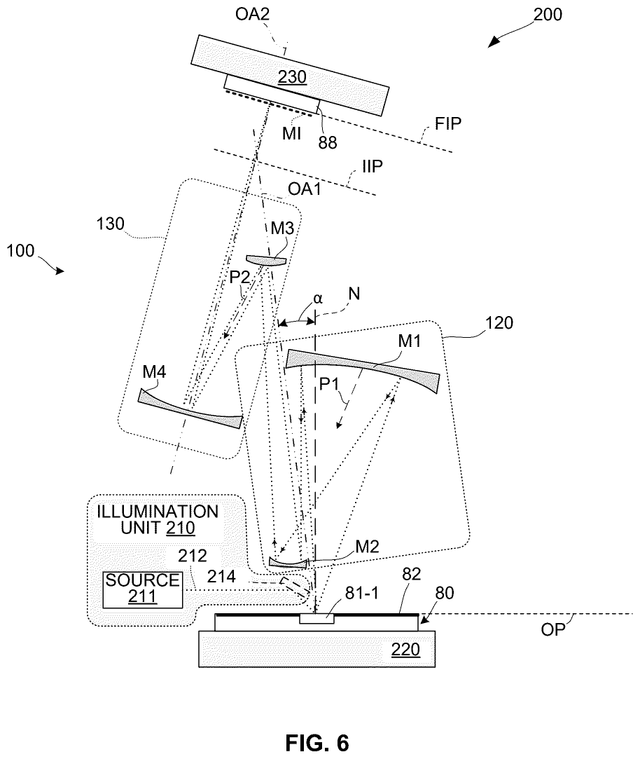

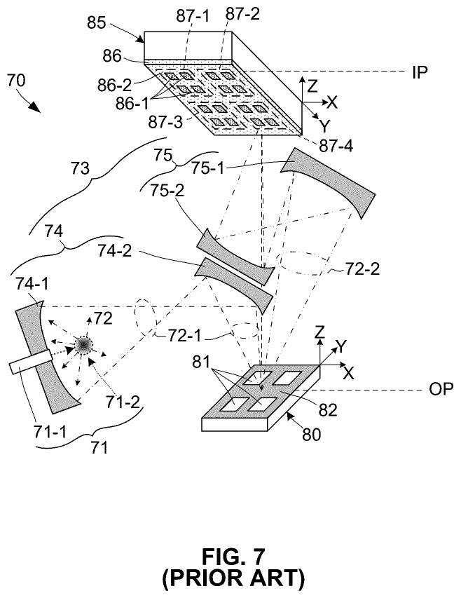

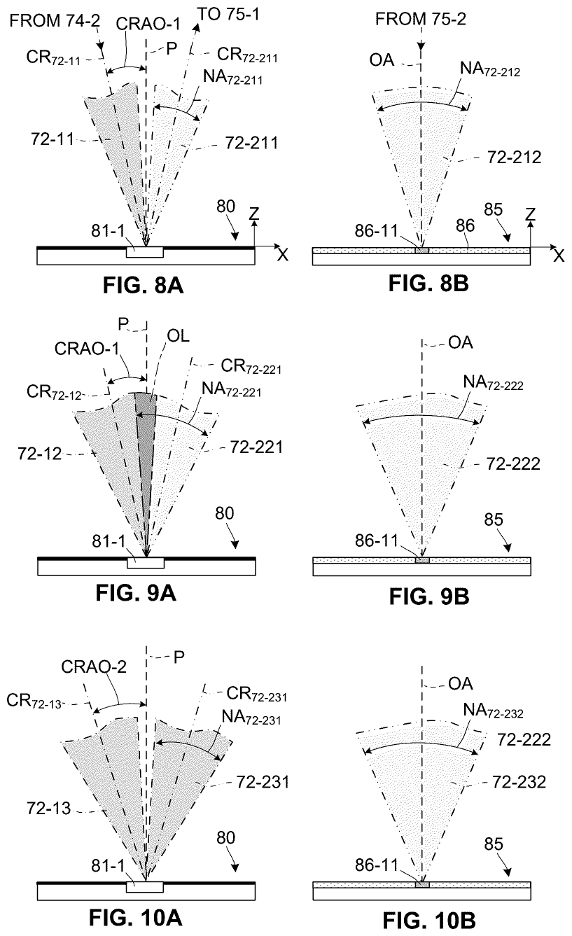

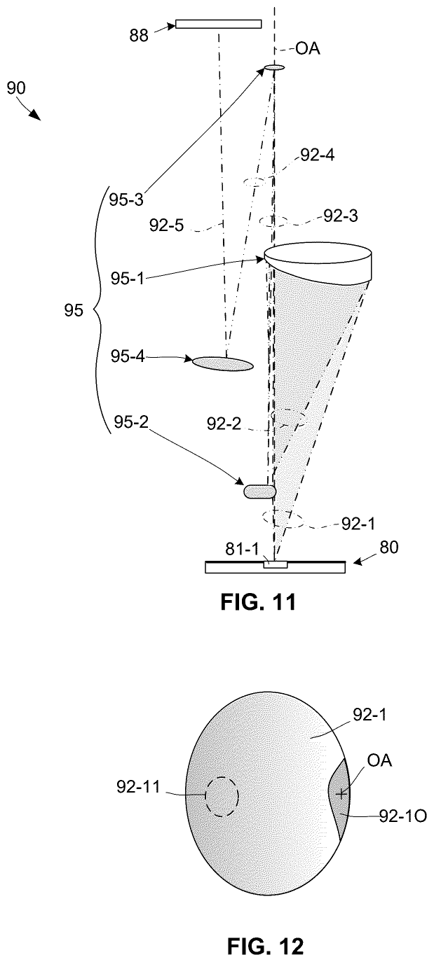

FIG. 6 shows an inspection system 200 that utilizes catoptric system 100 to generate a magnified image MI on an image sensor 88 using patterned light beams reflected from a reticle (object) 80. Inspection system 200 includes an illumination unit 210, a first stage (e.g., X-Y table) 220 configured to support and move (scan) reticle 80 and a second stage 230 configured to support and move (scan) image sensor 88 in synchronization with first stage 220. Inspection system 200 also includes a controller (not shown) that controls the operation of illumination source 210, first stage 220 and second stage 230 during high magnification inspection of reticle 80. Illumination unit 210 includes an illumination source 211 and illumination optics 214 that are cooperatively configured to direct homogenous incident light 212 onto an upper surface of reticle 80. Illumination unit 210 is depicted in greatly simplified form for clarity and brevity, and is constructed and operated in a manner known to those skilled in the art. In one embodiment illumination unit 210 generates and directs homogenous EUV light 212 having a nominal wavelength of 13.5 nm onto reticle 80 in a manner similar to that described with reference to FIG. 7. In other embodiments, illumination unit 210 may be configured to generate light (electromagnetic radiation) 212 at other wavelengths that may benefit from the use of catoptric systems (e.g., other EUV light in the range of 10 to 121 nm, or X-ray radiation with a wavelength below 10 nm). In one embodiment, illumination source 210 is controlled to generate and direct homogenous EUV light 212 onto reticle 80 as a series of pulses, where each EUV light pulse includes corresponding light beams that are directed through a first pupil (not shown) onto a corresponding elongated portion of reticle 80. Each light beam of each incident light pulse is either reflected from one of reticle's micro-mirrors 81 or is absorbed by (i.e., not reflected from) absorber 82. The reflected light beams form patterned light that is directed away (e.g., upward) from reticle 80 and projected by way of catoptric system 100 to image sensor 88. In one embodiment, the patterned light beams produced in response to each pulse are directed onto a corresponding elongated portion of the image sensor 88 by way of a second pupil (not shown), whereby the partial image (pattern of reflected EUV light) is captured and stored. After each pulse, first stage 220 incrementally shifts reticle 80 and second stage 230 incrementally shifts image sensor 88, and a next pulse is directed onto a second elongated portion of reticle 80, light reflected from the second portion is transmitted by the optical system 100 onto a corresponding second elongated portion of the image sensor 88, and a second partial image is captured and stored. This process is repeated until image data is generated for a desired scan region of reticle 80 has been collected.

As implemented by inspection system 200, catoptric system 100 is arranged relative to stages 220 and 230 such that an upper surface of reticle 80 forms object plane OP and such that a light receiving surface of image sensor 88 forms final image plane FIP. Scheimpflug optics 120 utilize mirror M1 to collect the patterned light beams reflected from the object 80 and to redirect the patterned light beams along first optical path P1 toward mirror M2. Mirror M2 redirects the patterned light beams along first optical axis OA1 such that the redirected light beams 92-3 form an intermediate image at intermediate image plane IIP. Both first optical axis OA1 and intermediate image plane IIP are oblique to object plane OP (e.g., first optical axis OA1 forms an acute angle α relative to normal direction N). Non-concentric optics 130 include mirror M3 configured to redirect parallel patterned light beams from first optical axis OA1 along second optical path P2 toward mirror M4, and mirror M4 is configured to redirect these patterned light beams along second optical axis OA2 such that the redirected light beams 92-5 are focused to form magnified image MI at the light receiving surface of image sensor 88. Both intermediate image plane IIP and final image plane FIP are perpendicular to second optical axis OA2.

In some embodiments inspection system 200 includes an image processing system (not shown) that is configured to process the captured/stored image data (e.g., to stitch together the image data captured during each incremental pulse/exposure), thereby providing image data corresponding to a two-dimensional image of the scanned region of the reticle 80 in order to detect reticle defects (e.g., by comparing the two-dimensional image with known-good image data and identifying anomalies). In some embodiments the inspection system 200 also includes a repair system (not shown) that utilizes the two-dimensional image data to repair all identified reticle defects using known techniques. Image processing systems and repair systems are known in the art and may be utilized in conjunction with the image data processing the captured/stored image data.

The various embodiments of the structures and methods of this invention that are described above are illustrative only of the principles of this invention and are not intended to limit the scope of the invention to the embodiments described. For example, although the invention is described with specific reference to catoptric (mirror-based/reflective optical) systems used in high energy (e.g., EUV) systems and tools, the combined use of Scheimpflug optics and non-concentric optics may be beneficially utilized in dioptric (lens-based/transmissive) and catadioptric (both mirror-based/reflective and lens-based/transmissive) systems. Moreover, although described with specific reference to high magnification catadioptric systems, the combined use of Scheimpflug optics and non-concentric optics may be beneficially utilized in some low magnification catadioptric systems, such as in EUV manufacturing systems of the type described with reference to FIG. 7. Thus, the invention is limited only by the following claims and their equivalents.

1. A catoptric system for generating a magnified image using patterned light beams sourced from an imaged area, the imaged area being located on an object plane and the magnified image being generated on a final image plane, the catoptric system comprising:
a first plurality of mirrors configured and arranged in accordance with the Scheimpflug condition to collect the patterned light beams from the imaged area and to redirect the patterned light beams along a first optical axis such that the redirected light beams form an intermediate image at an intermediate image plane, wherein both the first optical axis and the intermediate image plane are oblique to the object plane; and
a second plurality of mirrors configured to redirect the light beams from the first optical axis to a second optical axis that is perpendicular to the intermediate image plane such that the redirected light beams form the magnified image at the final image plane.

2. The catoptric system of claim 1, wherein each mirror of the first plurality of mirrors and the second plurality of mirrors comprises a multilayer mirror stack configured to reflect extreme ultraviolet (EUV) light.

3. The catoptric system of claim 1,
wherein a first magnification of the first plurality of mirrors is in the range of 5× to 30×,
wherein a second magnification of the second plurality of mirrors is in the range of 10× to 50×, and
wherein a combined magnification of the first plurality of mirrors and the second plurality of mirrors is in the range of 50× to 1000×.

4. The catoptric system of claim 1, wherein the first plurality of mirrors are configured such that the first optical axis extends at a first oblique angle relative to the normal direction of object plane, said first oblique angle being in the range of 0.5° and 10°.

5. The catoptric system of claim 1, wherein the first plurality of mirrors comprises:
a first concave mirror positioned over object plane and configured/oriented to collect and reflect first light beams sourced from the imaged area such that the reflected light beams to converge along a first optical path; and
a second concave mirror positioned over the object plane and adjacent to the imaged area, the second concave mirror being configured/oriented redirect the reflected light beams from the first optical path such that the redirected light beams converge along the first optical axis between the second concave mirror and the intermediate image plane.

6. The catoptric system of claim 5, wherein at least a portion of the first concave mirror is positioned to receive and reflect a normal light beam portion of the first light beams that are directed perpendicular to the object plane.

7. The catoptric system of claim 6, wherein the first concave mirror is configured and positioned such that a focal point of the first concave mirror is located between the first concave mirror and the second concave mirror, whereby the reflected light beams reflected from the first concave mirror invert before arriving at the second concave mirror.

8. The catoptric system of claim 6, wherein the second concave mirror is offset from the imaged area such that the normal light beam portion is unimpeded by the second concave mirror.

9. The catoptric system of claim 5,
wherein the first and second concave mirrors comprise spherical mirrors respectively having first and second centers of curvature, and
wherein the first and second concave mirrors are positioned and arranged such that both the first and second centers of curvature coincide with the first optical axis.

10. The catoptric system of claim 5,
wherein the first and second concave mirrors comprise aspherical mirrors respectively having first and second symmetric axes, and
wherein the first and second concave mirrors are positioned and arranged such that both the first and second symmetric axes coincide with the first optical axis.

11. The catoptric system of claim 1, wherein the second plurality of mirrors comprises:
a third mirror positioned and configured to reflect the light beams passing along the first optical axis such that the reflected light beams are directed in parallel along a second optical path that extends at a fourth oblique angle relative to the first optical axis; and
a fourth mirror positioned and configured to redirect the reflected light beams directed along the second optical path such that the redirected light beams are directed along the second optical axis.

12. The catoptric system of claim 11, wherein the third mirror comprises a convex mirror that is located between the intermediate image plane and the second convex mirror.

13. The catoptric system of claim 11, wherein the third mirror comprises a concave mirror located between the intermediate image plane and the final image plane.

14. The catoptric system of claim 12,
wherein the fourth mirror comprises a concave mirror configured to magnify the redirected light beams directed along the second optical axis such that the magnified image is formed on the final image plane, and
wherein the intermediate image plane is located between the fourth mirror and the final image plane.

15. An inspection tool including:
a first stage configured to support an object in an object plane;
an illumination unit including an illumination source and illumination optics that are cooperatively configured to direct homogenous incident light onto the object;
a second stage configured to support an image sensor in a final image plane, and
a catoptric system configured to generate a magnified image on the image sensor using patterned light beams reflected from the object, the catoptric system comprising:
a first plurality of mirrors configured and arranged in accordance with the Scheimpflug condition to collect the patterned light beams reflected from the object and to redirect the patterned light beams along a first optical axis such that the redirected light beams form an intermediate image at an intermediate image plane, wherein both the first optical axis and the intermediate image plane are oblique to the object plane; and
a second plurality of mirrors configured to redirect the light beams from the first optical axis to a second optical axis that is perpendicular to the intermediate image plane such that the redirected light beams form the magnified image on the image sensor.

16. A method for inspecting an object disposed in an object plane, the method comprising:
directing homogenous incident light onto the object;
utilizing a first plurality of mirrors to collect light beams reflected from the object and to redirect the light beams along a first optical axis such that the redirected light beams form an intermediate image at an intermediate image plane, wherein both the first optical axis and the intermediate image plane are oblique to the object plane;
utilizing a second plurality of mirrors to redirect the light beams from the first optical axis to a second optical axis that is perpendicular to the intermediate image plane such that the redirected light beams form the magnified image at a final image plane that is parallel to the intermediate image plane; and
utilizing an image sensor disposed in the final image plane to capture the magnified image.
